(19) United States
(12) Patent Application Publication
(10) Pub. No.: US 2020/0057098 A1
(43) Pub. Date: Feb. 20, 2020

(54) MONITORING ARRANGEMENT FOR DOMESTIC OR COMMERCIAL ELECTRICAL APPLIANCES

(71) Applicant: Electrolux Appliances Aktiebolag, Stockholm (SE)

(72) Inventor: Luca Rizzo, Porcia PN (IT)

(21) Appl. No.: 16/349,828

(22) PCT Filed: Nov. 15, 2016
(86) PCT No.: PCT/EP2016/077673

§ 371 Date: May 14, 2019

(51) Int. Cl. G01R 19/25; G05D 23/19

(52) U.S. Cl. CPC G01R 19/2513; G05D 23/1917

(57) ABSTRACT

A domestic or commercial electric appliance having at least one electric load, an AC power supply input for receiving electric power from an AC power source to be supplied to the at least one electric load, and a current sensor for sensing an AC current absorbed by the electric appliance from the AC power source. The electric appliance has a processing unit for carrying out a harmonic analysis on a sensed AC current sensed by the current sensor and for driving the at least one electric load based on an outcome of the harmonic analysis.

### BACKGROUND OF THE INVENTION

### Field of the Invention

The present invention refers in general to the field of domestic or commercial (called also professional) electric appliances, and more particularly to a monitoring arrangement for domestic or commercial electric appliances like a domestic o commercial refrigerator, a domestic or commercial laundry washing machine, a domestic or commercial laundry dryer machine, a domestic or commercial combined laundry washing and drying machine, a domestic or commercial dishwasher, a domestic or commercial oven, an air conditioner, and the like, and in general for all those domestic or commercial electric appliances comprising at least one electric load adapted for being supplied with AC current.

### Overview of the Related Art

With the development of intelligent appliance technology, the proliferation of electric appliances provided with monitoring capabilities adapted to collect real-time information about their operating condition as well as about the surrounding environment is increasing. Such information may relate to a very large number of different aspects, such as the instantaneous power consumption of the appliance, the assessment of overload and/or malfunctioning conditions, the operating status of the various electric loads of the appliance, the condition of the AC power grid, and so on. Electric appliances provided with this capability may advantageously avail of this kind of information to improve their operating efficiency, such as for example by promptly signaling the occurrence of possible malfunctioning to the user or by optimizing the management of the electric power consumption. Moreover, environmental and economic reasons have brought to the diffusion of renewable electric power generation units (e.g. solar panels or wind turbines), whose electric power generation capabilities fluctuate based for example on the weather conditions. Therefore, in order to further improve their operating efficiency, intelligent electric appliances should be also aware of the real-time availability of electric power generated by said renewable electric power generation.

It is known that a reliable way for an electric appliance to obtain the information mentioned above is the monitoring of the AC current absorbed by the electric appliance itself (i.e. the overall current consumption of the electric appliance) by means of a current sensor.

For example, U.S. Pat. No. 4,741,170 discloses an improved control for a refrigerator. Critical components such as fresh food and freezer compartment temperature sensors, temperature set devices and baffle are sampled to confirm that each is operational. Upon diagnosis of a critical component failure or of multiple component failures, the control, using stored control parameters, operates the remaining components in a manner that will continue to preserve food.

U.S. Pat. No. 46,151,779 discloses an apparatus and method for detecting a failure in an automatic defrost system for a refrigerator. A current sensor means monitors the current supplied to the defrost heater and generates an “on” signal when current is sensed in the defrost heater circuit. A microprocessor determines the “off” time, that is the time between successive “on” signals, and compares this time to a predetermined reference time longer than the normal “off” time. A user discernible signal is generated upon detection of an “off” time greater than the reference time, signifying to the user that the defrost system is not operating properly, and corrective action may be necessary.

Patent JPH04359778 discloses a current transformer for detecting a current flowing a power source line. A controller compares the detected current value of the transformer with both upper and lower reference values, judges as a malfunction if the current value is out of both the upper and lower reference values, displays it on a display unit, and opens a relay switch of the component which is conducted at that time. In this case, the controller varies the upper reference values and the lower reference values in response to the component to be conducted of a dew-preventive heater, a defrosting heater, a driving motor of a fan and a compressor.

### SUMMARY OF THE INVENTION

Applicant has found that the known solutions mentioned above are not satisfactory, since they allow collecting only a subset of the information that can be exploited for improving the operation of an electric appliance.

Therefore, in view of the above, Applicant has faced the problem of how to improve the monitoring capabilities of electric appliances.

An aspect of the present invention related to a domestic or commercial (typically called also professional) electric appliance.

The domestic or commercial electric appliance comprises at least one electric load, an AC power supply input connectable to an AC power source for receiving electric power from said power source and arranged to supply electric power to said at least one electric load. The domestic or commercial electric appliance further comprises a current sensor for sensing an AC current absorbed by the electric appliance from the AC power source (i.e. the overall current consumption of the electric appliance), and a processing unit for carrying out an harmonic analysis on a sensed AC current sensed by the current sensor and for driving the at least one electric load based on an outcome of said harmonic analysis.

According to an embodiment of the present invention, said current sensor is a Hall current sensor.

According to an advantageous embodiment of the present invention, the processing unit is configured to calculate the total harmonic distortion of the sensed AC current, and to assess at least one among:
malfunctioning conditions of the at least one electric load, and
disturbances on the AC power source caused by other electric appliances, based on the calculated total harmonic distortion.

According to an advantageous embodiment of the present invention, said processing unit is configured to assess the presence, in a sensed AC current, of at least one secondary component oscillating at a frequency higher than a fundamental frequency of a main component of said sensed AC current.

According to an advantageous embodiment of the present invention, said processing unit is configured to drive the at least one electric load based on the assessment of the presence of said at least one secondary component.

According to an advantageous embodiment of the present invention, the processing unit is configured to detect if said at least one secondary component corresponds to an identification signal generated by a private available AC power supply comprised in the power source connected to said power supply input, and to drive said at least one electric load based on said identification signal.

According to an advantageous embodiment of the present invention, the processing unit is configured to carry out the harmonic analysis on the sensed AC current by applying a Fast Fourier Transform to the sensed AC current.

According to an advantageous embodiment of the present invention, the processing unit is configured to assess anomalous operation conditions or malfunction conditions of the at least one electric load based on the sensed AC current.

According to an advantageous embodiment of the present invention, the processing unit is further configured to assess the electric power consumption of the at least one electric load based on the sensed AC current.

According to an advantageous embodiment of the present invention, the processing unit is further configured to assess an overload condition of the AC power source based on sensed AC current.

According to an advantageous embodiment of the present invention, said electric appliance is a refrigerator, and said at least one electric load comprise at least one among an inverter unit, a compressor unit, and a defrost heating resistor.

According to an advantageous embodiment of the present invention, said electric appliance is a laundry washing machine, and said at least one electric load comprises at least one among a drain pump, a recirculation pump, a drum motor circuit, a heating resistor.

According to an advantageous embodiment of the present invention, said electric appliance is a laundry dryer machine, and said at least one electric load comprises at least one among a drum motor circuit, a heating resistor, a compressor unit, a fan.

According to an advantageous embodiment of the present invention, said electric appliance is an oven, and said at least one electric load comprises at least one among a heating resistor, a microwave generator unit, a fan.

Another aspect of the present invention relates to an electric system comprising a domestic or commercial (typically called also professional) electric appliance and an AC power source connected to the AC power supply input of said domestic or commercial electric appliance. Said AC power source is adapted to provide to said AC power supply input an electric power having a fundamental frequency being an utility frequency of a public available AC power supply.

According to an advantageous embodiment of the present invention, said AC power source includes at least one private available AC power supply. Each private available AC power supply is configured to generate additional electric power and a corresponding identification signal when activated. Said at least one secondary component corresponds to an identification signal.

### BRIEF DESCRIPTION OF THE DRAWINGS

These and others features and advantages of the solution according to the present invention will be better understood by reading the following detailed description of an embodiment thereof, provided merely by way of non-limitative example, to be read in conjunction with the attached drawings, wherein:

FIG. 1 is an exemplificative scenario comprising an electric appliance in which concepts according to embodiments of the present invention can be applied;

FIG. 2 is a very simplified schematic showing the main blocks of a current sensor comprised in the electric appliance of FIG. 1 according to an exemplary embodiment of the present invention, and

FIG. 3 is an equivalent circuit of the current sensor of FIG. 2 and of an electric load of the appliance of FIG. 1.

### DETAILED DESCRIPTION

Embodiments of the present invention relate to a domestic or commercial (called also professional) electric appliance designed to be supplied with AC current and provided with the capability of monitoring the AC current absorbed by the electric appliance itself (i.e. the overall current consumption of the electric appliance) for obtaining real-time information about its operating condition as well as about the surrounding environment.

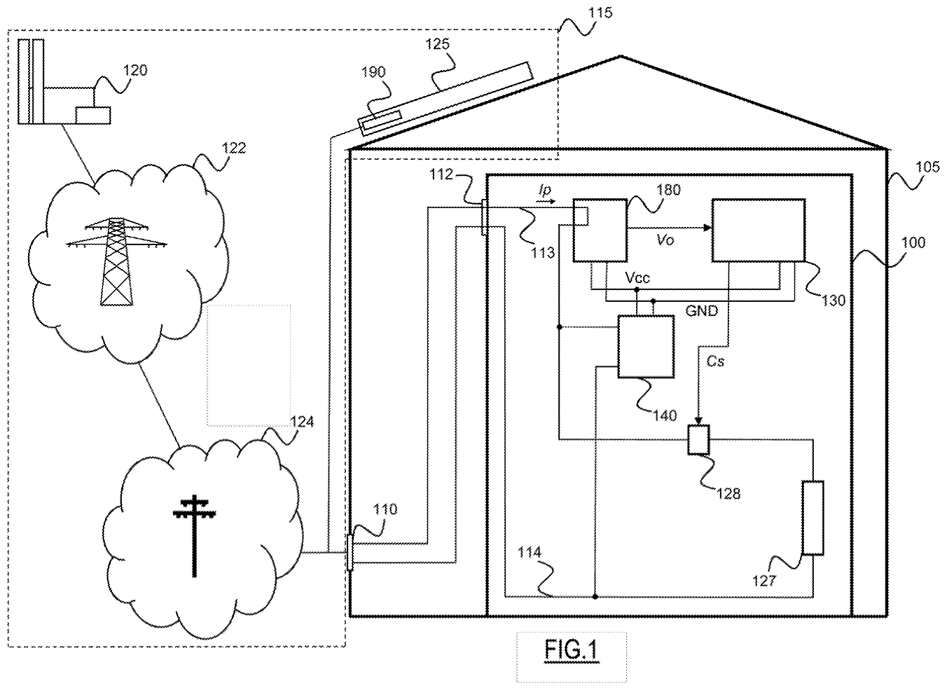

In order to describe advantageous embodiments of the present invention, reference will be now made to the exemplary scenario illustrated in FIG. 1, wherein an electric appliance 100, e.g., an electric household appliance—such as a refrigerator, a laundry washing machine, a laundry dryer machine, a combined laundry washing and drying machine, a dishwasher, an oven, an air conditioner and the like—located in a building 105, is connected to a power socket 110 for being supplied with AC power. Although in FIG. 1 the electric appliance 100 is an household appliance for the domestic use, similar considerations apply in case the electric appliance 100 is a commercial (or professional) electric appliance, i.e., an electrical appliance adapted to be employed in commercial (or professional) settings such as in restaurants, refectories, warehouses, laundromats, and the like.

The electric appliance 100 comprises an AC power supply input 112 electrically coupled to the power socket 110, e.g. by means of an AC power cord, for receiving electric power from an AC power source 115. The AC power supply input 112 preferably comprises a first terminal (line) 113 and a second terminal (neutral) 114. The voltage difference between line 113 and neutral 114 oscillates, for example at a frequency of 50 or 60 Hz, causing AC current to flow across a generic electric load when connected between line 113 and neutral 114.

In the present document, the term “AC power source” 115 is an umbrella term comprising known means/structures/units/apparatuses for generating and/or transforming, and/or delivering, and/or converting AC electric power; in the example shown in FIG. 1 electric power supplied by the AC power source 115 is available at the power socket 110.

Making reference to the exemplary scenario illustrated in FIG. 1, the AC power source 115 is preferably an interconnected network (electric grid) for delivering electricity from suppliers to consumers, which comprises, for example, public available AC power supplies 120, that produce electrical power, preferably high-voltage transmission grids 122 comprising high-voltage transmission lines for carrying power from the (typically distant) public available AC power supplies 120 to demand centers, and, preferably, medium-voltage distribution grids 124 for connecting individual customers, such as the building 105 wherein the power socket 110 is located. The oscillation frequency of voltage difference between line 113 and neutral 114 generated by the AC power source 115, e.g., by at least one public available AC power supply 120, is also referred to as utility frequency.

In the present document, by “public available AC power supply” it is intended any kind of AC power station which is managed by an electric utility and is adapted to generate AC power to be delivered to a plurality of users, for example having made a subscription to such electric utility. Examples of public available AC power supplies may comprise fossil-fuel power stations, nuclear stations, hydro-electric stations, photovoltaic power stations, and the like.

The AC power source 115 may advantageously further comprise at least one private available AC power supply 125—also referred to as additional AC power supply-, such as a renewable power supply, for example a photovoltaic panel or a wind turbine, preferably, but not necessarily, directly located at the building 105 or close to the latter.

In the present document, by “private available AC power supply” it is intended any kind of AC power generator which is directly managed by a private user. Examples of private available AC power supplies 125 may comprise domestic photovoltaic panels and micro-wind turbine generators.

Such private available AC power supply 125 is configured to provide additional electric power to be available at the power socket 110 when such private available AC power supply 125 is in the condition to operate, e.g., in presence of sun rays or in presence of wind, and when is actually activated.

The electric appliance 100 comprises one or more electric loads 127 (only one visible in FIG. 1).

In case the electric appliance 100 is a refrigerator, possible non limitative examples of electric loads 127 may comprise a compressor unit for the circulating refrigerant, an inverter for driving the compressor unit, and a heating resistor for performing defrost cycles.

If the electric appliance 100 is a laundry washing machine, possible non limitative examples of electric loads 127 may comprise a motor for rotating a washer drum, an inverter for driving such motor, a drain pump for draining washing liquid from a washing tub, a recirculation pump for recirculating washing liquid, and a heating resistor for heating washing liquid.

If the electric appliance 100 is a laundry dyer machine, possible non limitative examples of electric loads 127 may comprise a motor for rotating a dryer drum, an inverter for driving such motor, a fan for propelling drying air, a heating resistor for heating drying air, and a compressor for the heat pump circuit.

If the electric appliance 100 is an oven, possible non limitative examples of electric loads may comprise a heating resistor for heating a cooking chamber, a microwave generator for generating microwaves radiation to be provided in the cooking chamber, and a fan for circulating air inside the cooking chamber.

The generic electric load 127 is preferably driven by a respective driving apparatus 128 which may advantageously comprise a relay, a TRIAC, or other controllable switching means preferably arranged to selectively couple said electric load 127 between line 113 and neutral 114, to enable AC current flowing across the electric load 127.

For example, according to an advantageous embodiment of the present invention, the driving apparatus 128 has preferably a first conduction terminal electrically coupled to the line 113, preferably a second conduction terminal coupled to a first terminal of the respective electric load 127, and, preferably, a control terminal adapted to receive a control signal CS from a processing unit (control unit) 130 of the appliance 100 (e.g., consisting of or comprising a microprocessor) directed to manage the operation of the appliance 100. Without descending into technical details well known to those skilled in the art, the driving apparatus 128 is preferably designed to be switched between a non-conductive condition, in which its first conduction terminal is electrically decoupled from its second conduction terminal, and a conductive condition, in which its first conduction terminal is electrically coupled with its second conduction terminal based on the control signal CS received by the driving apparatus 128.

When the driving apparatus 128 is in the non-conductive condition, the respective electric load 127 is electrically decoupled from the line 113, and therefore no current flows across it.

When the driving apparatus 128 is in the conductive condition, the respective electric load 127 is electrically coupled between line 113 and neutral 114, so that AC current flows across the electric load 127 itself. As it is well known to those skilled in the art, if the driving apparatus 128 is for example a TRIAC, the electric power transferred to the electric load 127 can be adjusted by setting the control signal (S in such a way to switch the TRIAC in the conductive state at an adjustable time (phase angle) after the start of each half-cycle of the AC voltage difference between line 113 and neutral 114, thereby altering the actual voltage difference waveform applied between the electric load 127 terminals and so changing its RMS (Root Mean Square) effective value.

Clearly, other possible kind and arrangements of driving apparatus 128 can be used, provided that they are able to selectively allow/prevent the AC current to flow across the electric load 127.

Also the processing unit (control unit) 130 of the appliance 100 can be different and/or differently arranged/connected with respect to the one shown in FIG. 1.

The electric appliance 100 preferably comprises an AC-DC conversion circuit (only conceptually illustrated in the figure and denoted, as a whole, by the reference 140), comprising, for example, transforming, rectifying and regulation components for receiving an AC voltage (e.g., from line 113 and neutral 114) and providing, for example, one or more DC voltages, such as a ground voltage GND and a DC supply voltage Vcc (e.g., a 3V, 5V or 12V DC voltage with respect to the ground voltage GND). The DC voltage(s) generated by the AC-DC conversion unit 140 can be for example used for supplying—among others—the control unit 130 directed to manage the operation of the appliance 100.

The electric appliance 100 further comprises a current sensor 180 configured to measure, preferably in real-time, the (total) AC current Ip absorbed by the electric appliance 100 through the power socket 110 (i.e. the overall current consumption of the electric appliance); advantageously the current sensor 180 is configured to provide the outcome of such measure to the control unit 130. As will be described in detail in the following of the present description, the control unit 130 is preferably configured to set the control signal CS—for controlling the driving apparatus 128—based on the measure carried out by the current sensor 180.

The current sensor 180 is preferably connected in series to the line 113 at the AC power supply input 112, preferably in order to be upstream the other elements included in the electric appliance 100. Preferably, but not necessarily, the current sensor 180 may be supplied with the DC voltages GND and Vec generated by the AC-DC conversion unit 140.

According to an advantageous embodiment of the present invention, the current sensor 180 is a current sensor exploiting the Hall effect to measure the AC current absorbed by the electric appliance 100 (i.e. the overall current consumption of the electric appliance).

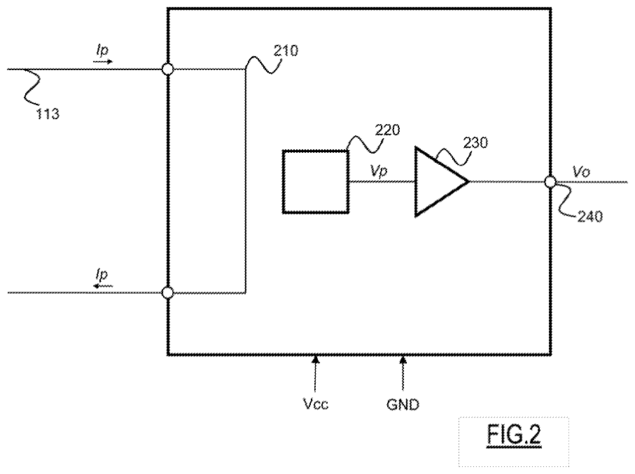

FIG. 2 is a very simplified schematic showing the main blocks of the current sensor 180 according to an exemplary embodiment of the present invention. The current sensor 180 preferably comprises a primary conduction path 210 adapted to be crossed by the AC current Ip absorbed by the electric appliance 100. The current sensor preferably further comprises an (e.g., integrated) Hall sensor module 220 adapted to sense the magnetic field generated by the passage of the AC current Ip across the primary conduction path 210 and to generate a corresponding electric signal, for example a corresponding voltage Vp, proportional to the sensed magnetic field. The corresponding electric signal, e.g. voltage Vp, is preferably fed to a conditioning section 230 of the current sensor 180 (preferably comprising filters, amplifiers and offset circuits) for the generation of a corresponding output electric signal, e.g. a corresponding output voltage Vo, that is preferably made available at an output terminal 240 of the current sensor 180. The output electric signal, e.g. output voltage Vo generated by the conditioning section 230 is an AC electric signal, e.g., an AC voltage proportional to the AC current Ip, and advantageously follows in real time the oscillations of the latter with the same frequency and phase. In order to maximize the output dynamic, the conditioning section 230 is preferably arranged such as to introduce in the output voltage Vo an offset, preferably equal to half the value of the supply voltage Vcc.

The output terminal 240 of the current sensor 180 is preferably connected to an analog input terminal of the control unit 130 (see FIG. 1) to provide the output voltage Vo to the latter. The control unit 130 is preferably configured to set the control signal CS for controlling the driving apparatus 128 based on the received output voltage Vo, as will be described in following portions of the present description. Without descending into particulars well known to those skilled in the art, the control unit 130 may preferably comprise a sampling unit coupled to the analog input terminal for sampling the output voltage Vo received from the current sensor 180; the control unit 130 may preferably comprise an analog-to-digital conversion unit adapted to convert the analog sampled values generated by the sampling unit into digital values which can be processed by other (e.g., firmware, or software) processing modules of the control unit 130. Moreover, similar considerations apply if the output voltage Vo is provided to the control unit 130 in a different way, for example, with a sampling unit and an analog-to-digital conversion unit located outside the control unit 130 itself.

Compared with other known current sensors typically installed in electric appliances—such as the so-called shunt current sensors in which a sensing voltage is generated by amplifying the voltage drop on a resistor (“shunt resistor”) in series to the path wherein the current to be sensed is flowing—the current sensor 180 has a very low input electrical resistance, for example 0.6 mΩ, given by the resistance of the primary conduction path 210. Thanks to the low input electrical resistance value, the current sensor 180 has a very low power consumption. Moreover, compared to other current sensors, such as the shunt current sensor, the current sensor 180 has the primary conduction path 210 that is advantageously galvanically insulated from the other parts of the current sensor 180.

Thanks to the current sensor 180, the control unit 130 is able to monitor, preferably in real-time, the AC current Ip absorbed by the electric appliance 100 (i.e. the overall current consumption of the electric appliance). In this way, the control unit 130 obtains, preferably real-time, information about the electric appliance 100 operating condition, and preferably also about the surrounding environment, and can control the electric appliance 100 according to such information.

For example, the control unit 130 may detect anomalous conditions of the electric load 127 based on the monitored current Ip. If the current Ip is too high, it may mean that a short-circuit is occurred, or, in case the electric load 127 is a compressor or a motor, it may mean that the rotor of the compressor or of the motor is blocked. If the current Ip is too low, it may mean the presence of open circuits. In any case, the control unit 130 may use the acknowledged information to inform the user (e.g., through audio and/or visual warning signals) or to take measures (e.g., turning off the electric loads 127).

The control unit 130 may preferably assess malfunctioning conditions of each individual electric load 127 of the electric appliance 100 by considering the monitored current Ip absorbed by the electric appliance 100 (i.e. the overall current consumption of the electric appliance) at the activation of such individual electric load 127.

By knowing the electrical resistance of the electric loads 127, the control unit 130 may use the value of the monitored current Ip absorbed by the electric appliance 100 (i.e. the overall current consumption of the electric appliance) for having a, preferably real-time, measurement of the power consumed by the electric appliance 100, or obtaining measures of the voltage provided by the AC power source 115 at different times, for example for assessing possible anomalous conditions of the AC power source 115.

Preferably, the control unit 130 may also detect overloads in the AC power source 115 by checking if the utility frequency of the AC power source 115 (and, therefore, of the current Ip) is subjected to drifts.

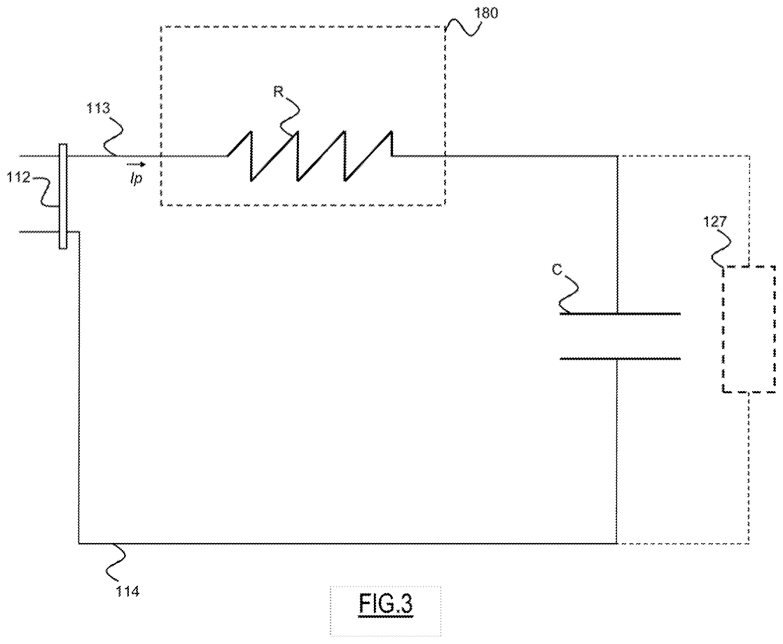

As can be seen in the equivalent circuit of FIG. 3, the input resistance of the current sensor 180, identified in FIG. 3 with reference R, forms a low-pass filter together with the equivalent capacitance of the electric loads 127, identified in FIG. 3 with reference C. As it is well known to those skilled in the art, the frequency of the main pole of a low-pass filter of this kind is inversely proportional to the value of the resistance R. Therefore, the lower the input resistance R, the wider the range of frequencies which is not filtered out by the low-pass filter.

Since the current sensor 180 according to the preferred embodiments of the present invention has a low input resistance, the control unit 130 may monitor the current Ip absorbed by the electric appliance 100 (i.e. the overall current consumption of the electric appliance) over a wide range of frequencies.

Making for example reference to an electric load equivalent capacitance C of 300 μF (which is a plausible value for the case in which the electric load 127 is a compressor of a refrigerator), using the current sensor 180 with an input resistance of 0.6 mΩ forms a low-pass filter having a main pole located at a frequency of about 884 kHz. Therefore, in this exemplary case, the control unit 130 is able to detect components of the current Ip oscillating at frequencies up to 884 kHz.

If a current sensor comprising a shunt resistor was used in place of the current sensor 180, the main pole would be at a very lower frequency. For example, a typical input resistance of a current sensor comprising a shunt resistor may be 1Ω, and therefore, with a same electric load equivalent capacitance of 300 μF, the main pole would be at a frequency of about 531 Hz. In this case, the control unit 130 would be able to detect components on the current Ip occurring at frequencies up to 531 Hz only (less than three order of magnitude lower than with the current sensor 180 exploiting the Hall effect).

In view of the above, since the current sensor 180 according to an advantageous embodiments of the present invention has a low input resistance, the control unit 130 is allowed to receive from the current sensor 180 a signal having a harmonic content very similar to the one of the current Ip, because the number of frequency components that are filtered out is strongly reduced. Thanks to this feature, according to an advantageous embodiment of the present invention the control unit 130 is allowed to carry out an harmonic analysis on a signal which is very similar (from the frequency point of view) to the current Ip, comprising a large portion of the whole frequency content of the current Ip (i.e. up to frequencies corresponding to its main pole). If a different current sensor was employed (which is however possible according to the invention) having a higher input resistance, the control unit 130 would receive a signal comprising a lower portion of the whole frequency content of the current Ip (comprising less frequency components), and therefore a harmonic analysis would be less reliable.

According to an advantageous embodiment of the present invention, the control unit 130 is configured to carry out said harmonic analysis by using frequency domain operations such as the Fast Fourier Transform (FFT), for example implemented by firmware and/or software modules of the control unit 130.

For example, according to an advantageous embodiment of the present invention, the control unit 130 may assess the presence of secondary components of the monitored current Ip oscillating at frequencies higher than the fundamental frequency (i.e., the utility frequency) of the main component of the monitored current Ip.

As another example, according to an advantageous embodiment of the present invention, the control unit 130 may calculate the total harmonic distortion THD of the AC current Ip absorbed by the electric appliance 100 to obtain an accurate measurement of the harmonic distortion present (e.g. the ratio of the sum of the powers of all harmonic components to the power of the fundamental frequency of the AC current Ip).

Based on the outcome of the harmonic analysis (e.g. the assessment of secondary components and/or the calculation of the total harmonic distortion THD), the control unit 130 according to embodiments of the present invention can detect malfunctioning conditions of the electric loads 127, for example a compressor motor bad condition or a compressor inverter failure, and detect disturbances on the AC power source 115 caused by other electric appliances fed by the same AC power source 115.

For example, according to an advantageous embodiment of the present invention, through the harmonic analysis, e.g. carried out by means of a FFT, the control unit 130 may detect spurious frequency contents on the spectrum of the AC current Ip (carrier or modulation). If spurious frequency contents are detected, the control unit 130 may diagnose a malfunctioning condition of the electric loads 127, such as an inverter malfunction—i.e., a partially damaged driver—or an incorrect motor condition.

According to an advantageous embodiment of the present invention, the harmonic analysis carried out on a signal having a harmonic content very similar to the one of the current Ip, made possible by having the low input resistance current sensor 180, can be advantageously exploited for assessing, preferably in real time, whether there are private available AC power supplies, such as the renewable power supply 125 (e.g., photovoltaic panel) of FIG. 1, which are providing additional electric power or not.

Making reference to FIG. 1, the renewable power supply 125 may preferably comprise a modulator unit 190 adapted to modulate the AC current generated by the renewable power supply 125 itself with an AC identification signal oscillating at a higher frequency (such as for example in the range 30-300 KHz) when the renewable power supply 125 is operating and is delivering additional electric power.

In this way, according to an advantageous embodiment of the present invention, if the results of the harmonic analysis carried out on the AC current Ip absorbed by the electric appliance 100 provides that the AC current Ip comprises a component oscillating at the frequency of a known identification signal, the control unit 130 may assess that the renewable power supply 125 corresponding to said specific identification signal is currently delivering electric power. Moreover, the control unit 130 may also advantageously comprise a demodulation unit configured for demodulating Power Line Communication (PLC) signals transmitted by the private available AC power supplies, such as the renewable power supply 125.

According to an advantageous embodiment of the present invention, the possibility of knowing, preferably in real time, if renewable power supplies 125 are currently delivering electric power or not, can be advantageously exploited to program the operation of the electric appliance 100 according to an optimized schedule, for example to reduce costs. For example, if the electric appliance 100 is a washing machine, the execution of a washing cycle may be temporarily paused by the control unit 130 until a renewable power supply 125 is assessed to be actually delivering additional electric power.

Naturally, in order to satisfy local and specific requirements, a person skilled in the art may apply to the solution described above many logical and/or physical modifications and alterations.

More specifically, although the present invention has been described with a certain degree of particularity with reference to preferred embodiments thereof, it should be understood that various omissions, substitutions and changes in the form and details as well as other embodiments are possible. In particular, different embodiments of the invention may even be practiced without the specific details set forth in the preceding description for providing a more thorough understanding thereof, on the contrary, well-known features may have been omitted or simplified in order not to encumber the description with unnecessary details. Moreover, it is expressly intended that specific elements and/or method steps described in connection with any disclosed embodiment of the invention may be incorporated in any other embodiment.

For example, even if in the description reference has been explicitly made to the use of a current sensor configured to exploit the Hall effect, the concepts of the present invention can be applied to other types of current sensors adapted to measure the (total) AC current absorbed by the electric appliance (i.e. the overall current consumption of the electric appliance), provided that the input resistance thereof is sufficiently low (e.g., from 0.1 to 1 mΩ) to generate a corresponding signal to be provided to the control unit having a harmonic content sufficiently similar to the one of the current absorbed by the electric appliance.

1. A domestic or commercial electric appliance comprising:
at least one electric load;
an AC power supply input connectable to an AC power source for receiving electric power from the AC power source and arranged to supply the electric power to the at least one electric load;
a current sensor configured to sense an AC current absorbed by the electric appliance from the AC power source;
a processing unit configured to perform a harmonic analysis on a sensed AC current sensed by the current sensor and to drive the at least one electric load based on an outcome of the harmonic analysis.

2. The domestic or commercial electric appliance according to claim 1, wherein the current sensor is a Hall effect current sensor.

3. The domestic or commercial electric appliance of claim 1, wherein the processing unit is configured to calculate a total harmonic distortion of the sensed AC current, and to assess, based on the calculated total harmonic distortion at least one among:
a malfunctioning condition of the at least one electric load, and
a disturbance on the AC power source caused by other electric appliances.

4. The domestic or commercial electric appliance of claim 1, wherein:
the processing unit is configured to assess a presence, in the sensed AC current, of at least one secondary component oscillating at a frequency higher than a fundamental frequency of a main component of the sensed AC current.

5. The domestic or commercial electric appliance of claim 4, wherein the processing unit is configured to drive the at least one electric load based on the assessment of the presence of the at least one secondary component.

6. The domestic or commercial electric appliance of claim 4, wherein the processing unit is configured to detect if the at least one secondary component corresponds to an identification signal generated by a private available AC power supply comprised in the power source connected to the power supply input, and to drive the at least one electric load based on the identification signal.

7. The domestic or commercial electric appliance of claim 1, wherein the processing unit is configured to carry out the harmonic analysis on the sensed AC current by applying a Fast Fourier Transform to the sensed AC current.

8. The domestic or commercial electric appliance of claim 1, wherein the processing unit is configured to assess an anomalous operation condition or a malfunction condition of the at least one electric load based on the sensed AC current.

9. The domestic or commercial electric appliance of claim 1, wherein the processing unit is further configured to assess the electric power consumption of the at least one electric load based on the sensed AC current.

10. The domestic or commercial electric appliance of claim 1, wherein the processing unit is further configured to assess an overload condition of the AC power source based on the sensed AC current.

11. The domestic or commercial electric appliance of claim 1, wherein the electric appliance is a refrigerator, and wherein the at least one electric load comprises at least one among:
an inverter unit;
a compressor unit; and
a defrost heating resistor.

12. The domestic or commercial electric appliance of claim 1, wherein the electric appliance is a laundry washing machine, and wherein the at least one electric load comprises at least one among:
a drain pump;
a recirculation pump;
a drum motor circuit; and
a heating resistor.

13. The domestic or commercial electric appliance of claim 1, wherein the electric appliance is a laundry dryer machine, and wherein the at least one electric load comprises at least one among:
a drum motor circuit;
a heating resistor;
a compressor unit; and
a fan.

14. The domestic or commercial electric appliance of claim 1, wherein the electric appliance is an oven, and wherein the at least one electric load comprises at least one among:
a heating resistor;
a microwave generator unit; and
a fan.

15. The domestic or commercial electric appliance of claim 1, wherein the AC power supply input is configured to receive from the AC power source, electric power having a fundamental frequency being a utility frequency of a publicly available AC power supply

16. The domestic or commercial electric appliance of claim 14, wherein:
the AC power source includes at least one private available AC power supply, each private available AC power supply being configured to generate additional electric power and a corresponding identification signal when activated;
the at least one secondary component corresponds to an identification signal.
